(19) United States
(12) Patent Application Publication
(10) Pub. No.: US 2015/0001694 A1
(43) Pub. Date: Jan. 1, 2015

(54) INTEGRATED CIRCUIT DEVICE PACKAGE WITH THERMAL ISOLATION

(71) Applicant: Texas Instruments Incorporated, Dallas, TX (US)

(72) Inventors: Peter John Hopper, San Jose, CA (US); Roozbeh Parsa, San Jose, CA (US)

(21) Appl. No.: 13/932,891

(22) Filed: Jul. 1, 2013

(51) Int. Cl. H01L 23/495

(52) U.S. Cl. CPC H01L 23/49568
USPC 257/675

(57) ABSTRACT

An integrated circuit (IC) package having an IC device; a heat source operably associated with said IC device; an electrical substrate operably electrically connected to the IC device; and a thermal isolation mat positioned between the IC device and the electrical substrate and having a base surface, a ceiling structure and a plurality of spaced apart elongate members positioned between the base surface and the ceiling structure. Other heat isolation structures are also disclosed.

### BACKGROUND

Most integrated circuit (IC) devices are designed to run as cool as possible. Many different types of heat dissipation and/or cooling systems have been developed to cool IC packages. It is rarely desirable to keep heat in an IC package. However, some micro-fabricated systems have a fixed temperature operating requirement. In some cases this required operating temperature may be above ambient. Thus, the system may require an integral heater element to maintain the desired operating temperature. The integral heater element of such systems often uses a significant portion of the available system power.

An example of a system in which an internal heating element is employed is an integrated quantum optical device package. An integrated quantum optical device package typically includes an alkaline metal cell with an operating temperature of 50° C. to 110° C. Other components include at least one IC device, such as, for example, a semiconductor die, a quartz resonator, a quartz oscillator, a miniature resonator, a miniature oscillator, a gyroscope, an accelerometer, a laser, an LED or an optical sensor. The package may include other small electrical devices as well such as, for example, passive components, heating devices and temperature sensors. The IC device is often mounted on a die attachment pad portion of a leadframe. The leadframe enables the IC device and any other components in the package to be electrically connected to other electronics.

In many IC packages an IC device and a portion of the leadframe are often enclosed in a protective casing that forms a package enclosure. In many cases the leadframe, in addition to providing electrical connections, also transfers heat from the IC device to the environment outside the package enclosure. However, in some cases where it is desirable to heat the IC device for maintaining it at an optimal operating temperature, heat dissipation through the leadframe is not desirable.

A patent application entitled EXTENDING RADIATION TOLERANCE BY LOCALIZED TEMPERATURE ANNEALING OF SEMICONDUCTOR DEVICES of James F. Salzman & Charles Hadsell, Ser. No. 13/309,393 filed Dec. 1, 2011, is hereby incorporated by reference for all that it discloses. U.S. Pat. No. 7,215,213, issued May 8, 2007 of Mark J. Mescher for APPARTUS AND SYSTEM FOR SUSPENDING A CHIP-SCALE DEVICE AND RELATED METHODS is also incorporated herein by reference for all that it discloses.

### BRIEF DESCRIPTION OF THE DRAWINGS

FIG. 1 is an exploded, side elevation view of an Integrated circuit package.

FIG. 2 is a bottom plan view of an integrated circuit package.

FIG. 3 is a flow chart of a method of making an IC package.

### DETAILED DESCRIPTION

In general, this specification discloses an integrated circuit (IC) package 10 including an IC device 12 and a heat source 22 operably associated with the IC device 12. The IC package 10 may be, for example, an integrated quantum optical device package or another type of IC package with an internal heating requirement. An electrical substrate 62, such as a leadframe 62, is operably electrically connected to the IC device 12 by a conductive strip 42. A thermal isolation mat 30 is positioned between the IC device 12 and the electrical substrate 62. The thermal isolation mat 30 has a base surface 97, a ceiling structure 32, 72, 82 and a plurality of spaced apart, elongate members 102, 104, 116, 118 that are positioned between the base surface 97 and the ceiling structure 32, 72, 82.

The conductor strip 42 that electrically connects the IC device 12 to the electrical substrate 62 may have a thermal bridge portion 50 that may be constructed from a refractory metal. The bridge portion may be positioned over a hole 35 in a portion of the ceiling structure 32.

The thermal isolation mat 30 substantially thermally isolates the IC device 12 from the electrical substrate 62 by limiting heat transfer through the physical structure that connects the IC device 12 to the electrical substrate 62. The thermal bridge portion 50 further reduces the transfer of heat from the IC device 12 to the electrical substrate 62 by limiting heat transfer to the electrical substrate 62 through the conductor strip 42 that electrically connects the IC device 12 to the electrical substrate 62. Having thus generally described an integrated circuit package 10, the integrated circuit package and alternative embodiments thereof will not be described in further detail.

The terms “top” and “bottom” as used herein do not imply any particular orientation with respect to a gravitational field, but rather are used in a relative sense for describing the spatial relationship between various objects, often based upon the orientation of a drawing figure. The terms “up,” “down,” “upper,” “lower,” “vertical,” “horizontal” and similar terms are used in the same manner. When describing integrated circuit package 10, the package is usually described with the electrical substrate 62, positioned at the bottom rather than the top. Again, since “top” and “bottom” are used in a relative sense, the description of the IC package 10 that is provided herein is accurate no matter how the IC package 10 may be oriented within Earth's gravitational field, top up, top down or lying on its side.

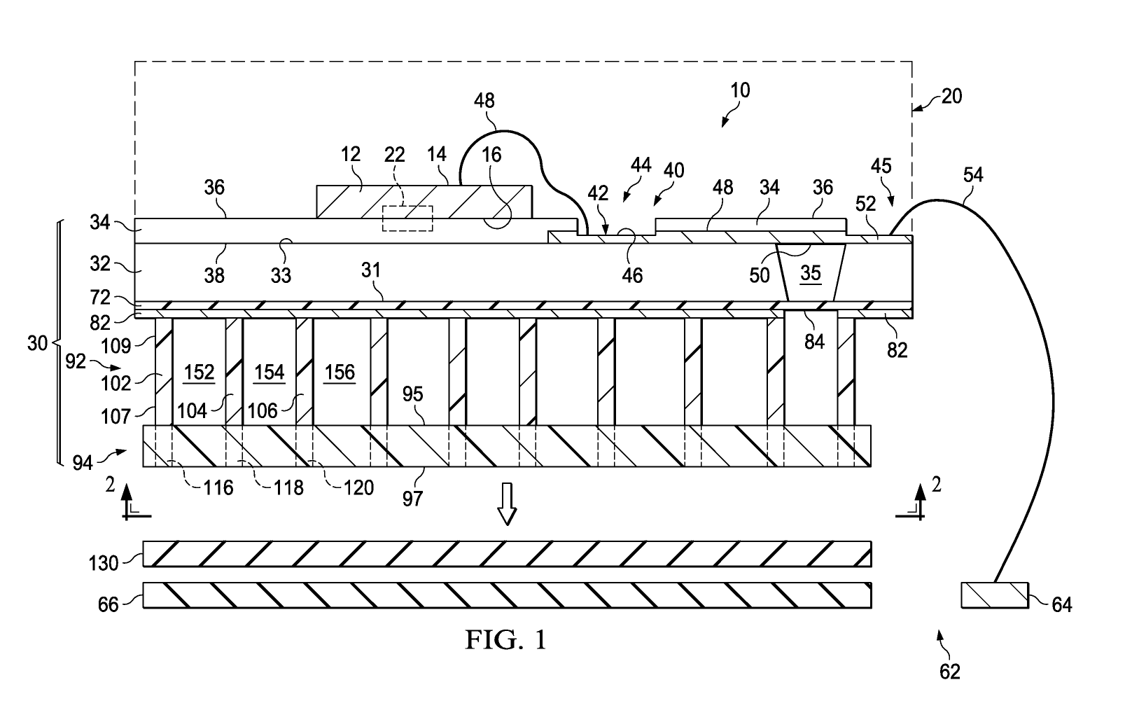

FIG. 1 illustrates an integrated circuit (IC) package 10. The package 10 includes an integrated circuit (IC) device 12 such as an IC die, light emitting diode (LED), infrared radiation (IR) photo diode, etc., having a top surface 14 and an opposite bottom surface 16. The IC device 12 is positioned within an enclosed area 20 that may or may not contain various other chip scale components. The IC device 12 is of a type that operates best within a predetermined temperature range that may be above ambient temperature in the environment in which the package 10 is used. A heating unit 22 is positioned in enclosed area 20 within or near the IC device 12 to maintain the IC device 12 within its predetermined temperature range. The enclosed area 20 may comprise an insulating structure. The heating unit 22 may incorporate a heat sensor (not shown) such as a thermistor that provides a control signal based upon the sensed temperature. The control signal is used in a conventional manner to control the heat output of the heating unit 22. The heating unit 22 and/or the associated heat sensor may be provided as an internal component of the IC device 12 or may be provided as one or more discreet devices located proximate to the IC device 12. The IC device 12 is mounted on a thermal isolation mat 30, which substantially thermally isolates the device 12 from the external environment, thereby reducing the power required by the heating unit 22 to maintain the IC device 12 within its optimum temperature range.

The thermal isolation mat 30, as shown in FIG. 1, may include a semiconductor substrate 32, sometimes referred to herein as a semiconductor layer 32, with a surface oxide layer 34, a metal layer 82, a metal oxide layer 72, and first and second epoxy layers 92, 94.

The semiconductor substrate 32 may be a silicon substrate having a bottom surface 31 and a top surface 33. The semiconductor substrate 32 may have a hole 35 therethrough extending through the bottom surface 31 and the top surface 33. The hole 35, in one embodiment, may have a generally trapezoid-shaped cross section. The hole 35 may be formed by etching the substrate 32, using conventional etching techniques, either from the top or the bottom, or by other means. In one embodiment the semiconductor substrate 32 may have a height (thickness) of about 100 μm. The substrate 32 may have an upper oxide layer 34 formed thereon as by chemical vapor deposition or other processes. The upper oxide layer 34 may comprise a conventional passivation layer. The upper oxide layer 34 comprises a top surface 36 that supports the IC device 12 and a bottom surface 38 that interfaces with the semiconductor substrate 32 top surface 33. In some embodiments the upper oxide layer 34 may have a thickness of about 0.1 μm to 0.5 μm. The heating unit 22 is embedded in the upper oxide layer 34 in some embodiments. The upper oxide layer 34 may have a first opening 40 therein positioned adjacent to the IC device 12 and may have a second opening 45 therein positioned above one terminal end portion of the semiconductor substrate 32.

An electrically continuous conductor strip 42 may extend from a position adjacent to or beneath the IC device 12 to a leadframe 62, on which the thermal isolation mat 30 is mounted. The conductor strip 42 may comprise a trace 44 formed on the top surface 33 of the semiconductor substrate 32. The trace 44 has an exposed contact pad portion 46 positioned in the opening 40. A bondwire 48 may electrically connect the IC device 12 to the contact pad portion 46. Trace 44 has a bridge portion 50 that extends over the hole 35 in the semiconductor substrate 32. The bridge portion 50 may be positioned below upper oxide layer 34. In one embodiment the length of the bridge portion 50 may be about 100 μm, the width (direction perpendicular to the drawing sheet) of the bridge portion 50 may be about 1 to 25 μm, and the thickness (height) of the bridge portion 50 may be about 0.03 to 0.3 μm. The bridge portion 50 may be formed from a refractory metal such as tungsten. A second contact pad portion 52 of trace 44 may be formed adjacent to the bridge portion 50. The second contact pad portion 52 may be electrically connected by a bondwire 54 to the leadframe 62, for example, to a lead portion 64 of leadframe 62. Although one means of connection of the IC device 12 to the trace 42 with a bond wire 48 is shown in FIG. 1, it will be understood that that other types of electrical connection could also be used. For example, the IC device 1 in another embodiment could be connected to an extended portion of the trace 44 that is positioned below the IC device 12 by a ball grid array type connection.

By using a refractory metal in the bridge portion 50 and by positioning the bridge portion 50 above an air pocket provided by the hole 35, heat transmission through the trace 44 may be substantially reduced. The longer the bridge portion 50 and the less heat conductive the refractory metal is, the greater the reduction in conductive heat loss through the trace 44. Rather than a single bridge portion 50 and a single hole 35, multiple bridge portions and holes could be provided to further reduce heat loss from the IC package 10 to the outside environment.

As further shown by FIG. 1, the second oxide layer 72 may be formed on the bottom surface 31 of semiconductor substrate 32. This oxide layer 72, in one embodiment, may have a thickness of about 0.1 μm to 0.5 μm. The oxide layer 72 provides a blocking layer for deposition of a metal layer 82.

In one embodiment the thermal isolation mat 30 is a laminate structure that includes a metal layer 82 deposited on the oxide layer 72. The metal layer 82 may be, for example, a thin copper layer which may have a thickness in a range of about 0.1 μm to 1.0 μm. A gap 84 may be provided in the metal layer 82 beneath the hole 35 in the semiconductor layer 32. The purpose of metal layer 82 is to lower the level of radiant heat loss.

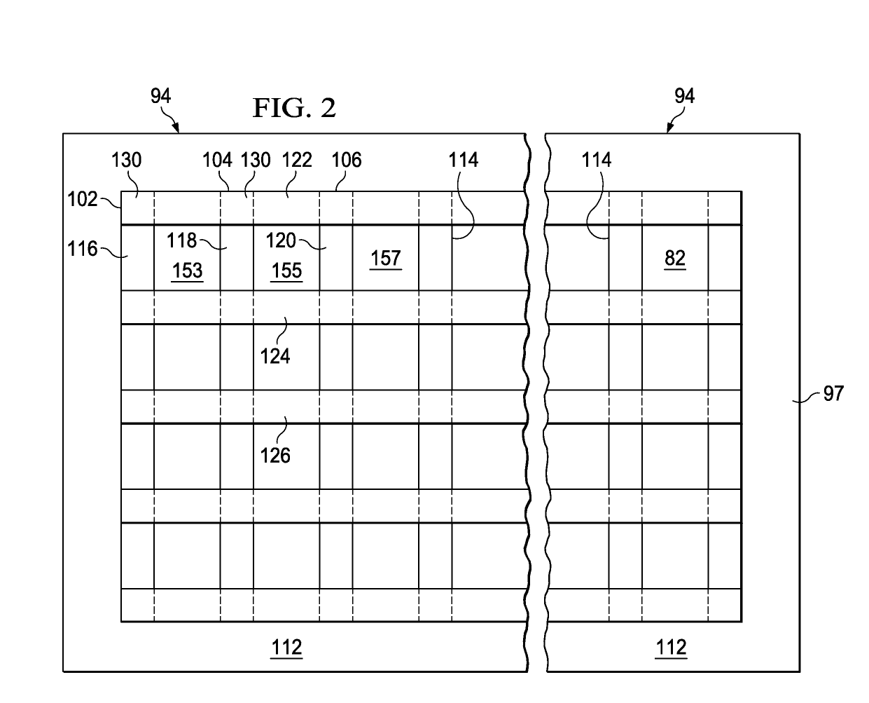

A first epoxy layer 92 and a second epoxy layer 94 are positioned beneath the metal layer 82, as shown in FIGS. 1 and 2. The first epoxy layer 92 is connected to the metal layer 82 and in one embodiment has a thickness of between about 50 μm and 100 μm. The first epoxy layer 92 comprises a plurality of epoxy columns 102, 104, 106, etc., arranged in a grid structure similar to that of the Parthenon. Each epoxy column has a lower end 107 and an upper end 109 and may have a diameter of between about 5 μm and 100 μm.

The second epoxy layer 94 has a top surface 95 and a bottom surface 97. In one embodiment the second epoxy layer 94 has a thickness of about 5 μm to 100 μm. As best shown in bottom plan view of FIG. 2, the second epoxy layer 94 may comprise a generally rectangular peripheral frame 112 and a lattice structure 114 that is positioned within the peripheral frame 112. The lattice structure 114 comprises a plurality of orthogonally arranged lattice strips or beams 116, 118, 120, etc. and 122, 124, 126, etc. Any number of beams may be used depending upon the size of the particular thermal isolation mat 30 that is to be made. Although an orthogonal arrangement of strips is illustrated, it will be understood that diagonal strips (not shown) could be added to further stiffen the structure of layer 94. The lattice beams 116,122, etc., overlap at nodes 130. One of the epoxy columns 102, 104, etc. may extend upwardly from each node 130. The upper end portion 109 of each column 102, etc., is attached to the metal layer 82.

The two layers 92, 94 may be formed by 3D lattice formation processes that include use of an epoxy that is photo imaged, exposed and cured, etc., to provide the various structures of layers 92 and 94. Such 3D formation processes are known in the art and are thus not further described herein.

These two epoxy layers 92, 94, have a plurality of interconnected air spaces 152, 154, 156, etc. defined by the columns 102, 104, 106, etc. in layer 92 and spaces 153, 155, 157, etc., between the various lateral beams 116, 118, etc. The air spaces 152, 153, etc., in layers 92 and 94 extend from the top of the leadframe 62 to the bottom of the metal layer 82. Air is a poor heat transmission medium. These air spaces serve to insulate, and thus thermally isolate, the IC device 12 from the leadframe 62. Epoxy/glass has a low coefficient of thermal conductivity and thus epoxy columns 102, 104, etc. of layer epoxy layer 92, and the epoxy beams 116, 118, etc., of epoxy layer 94 also serve to thermally isolate the IC device 12 from the leadframe 62 to which the IC device 12 is electrically connected.

The bottom surface of the second epoxy layer 94 may be attached, as by a die attach film layer 130, to a die attachment pad portion 66 of the leadframe 62. As a result of the thermal isolation mat 30 interposed between the IC device 12 and the leadframe 62 and the thermal bridge portion 50 and the associated air pocket formed by hole 35, far less heat is transmitted from the IC device 12 to the leadframe 62 than if the IC device 12 were directly mounted on the leadframe 62. Accordingly, far less energy needs to be provided to heating unit 22 to maintain the IC device 12 within its predetermined operating temperature range for any given period of time. This is particularly important when the IC package 10 is used in a harsh external environment or is placed at a remote location that is difficult or inconvenient to service. Examples include underground, buried, underwater and outer space applications and any application where battery power is a limiting factor in the operational longevity of the IC package 10

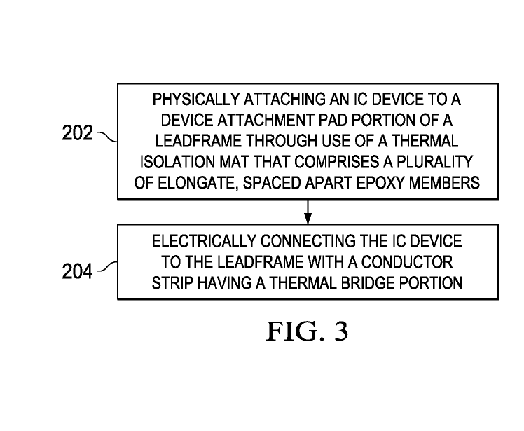

One method of making an IC package is shown by FIG. 3. The method may include, as shown at 202, physically attaching an IC device to a device attachment pad portion of a leadframe through use of a thermal isolation mat. The method may further include, as shown at 204, electrically connecting the IC device to the leadframe with a conductor strip having a thermal bridge portion.

While certain specific embodiments of an integrated circuit package and a production methodology have been described in detail herein, various alternative embodiments will be obvious to those skilled in the art after reading this disclosure. It is intended that the appended claims be broadly construed so as to cover all such alternative embodiments, except as limited by the prior art.

What is claimed is:

1. An integrated circuit (IC) package comprising:
an IC device;
a heat source operably associated with said IC device
an electrical substrate electrically connected to said IC device; and
a thermal isolation mat positioned between said IC device and said electrical substrate and having a base surface, a ceiling structure and a plurality of spaced apart elongate members positioned between said base surface and said ceiling structure.

2. The IC package of claim 1, wherein said base surface is a bottom surface of a base structure and wherein a portion of said plurality of spaced apart elongate members comprise a plurality of beams arranged in a lattice, and wherein said lattice is part of said base structure.

3. The IC package of claim 2 wherein said plurality of spaced apart elongate members comprise a plurality of columns extending between said base structure and said ceiling structure.

4. The IC package of claim 1, said ceiling structure comprising a metal layer.

5. The IC package of claim 1 said ceiling structure comprising a semiconductor layer.

6. The IC package of claim 5, said ceiling structure further comprising an oxide layer interfacing with said semiconductor layer and a metal layer interfacing with said semiconductor layer.

7. The IC package of claim 5, said IC device being electrically connected to said electrical substrate by a conductor comprising a thermal bridge portion.

8. The IC package of claim 7, said thermal bridge portion comprising refractory metal.

9. The IC packager of claim 7, said semiconductor layer comprising a hole extending therethrough, said thermal bridge portion extending across said hole in said semiconductor layer.

10. The IC package of claim 1, said electrical substrate comprising a leadframe having an IC device attachment pad, said base surface being attached to said IC device attachment pad.

11. The IC package of claim 9, said electrical substrate comprising a leadframe having an IC device attachment pad, said base surface being attached to said IC device attachment pad.

12. The IC package of claim 2 wherein said plurality of spaced apart elongate members comprise a plurality of columns extending between said base structure and said ceiling structure and wherein said plurality of beams arranged in a lattice are connected at a plurality of nodes and wherein said columns are attached to said nodes.

13. The IC package of claim 1, said spaced apart elongate members being made of epoxy.

15. The IC package of claim 12, said spaced apart elongate members being made of epoxy.

16. An IC package comprising:
an IC device;
a heat source operably associated with said IC device;
a leadframe positioned below said IC device; and
a conductor strip having a thermal bridge portion, said conductor strip electrically connecting said IC device to said leadframe through said thermal bridge portion.

17. The IC package of claim 16 further comprising:
a semiconductor layer positioned between said IC device and said electrical substrate; said semiconductor layer having a hole therein;
wherein said conductor strip bridge portion is made from refractory metal and extends over said hole in said semiconductor layer.

18. A method of making an IC package comprising:
physically attaching an IC device to a device attachment pad portion of a leadframe through use of a thermal isolation mat that comprises a plurality of elongate, spaced apart epoxy members; and
electrically connecting the IC device to the leadframe with a conductor strip having a thermal bridge portion.

19. The method of claim 18 comprising positioning said thermal bridge portion over a hole in said thermal isolation mat.

20. The method of claim 18 comprising making said thermal bridge portion from refractory metal.
